(19) United States
(12) Patent Application Publication
(10) Pub. No.: US 2024/0407105 A1
(43) Pub. Date: Dec. 5, 2024

(54) X-Y SHIELDING OF SIGNAL PATHS WITHIN PCBS

(71) Applicant: INTERNATIONAL BUSINESS MACHINES CORPORATION, ARMONK, NY (US)

(72) Inventors: Kyle Indukummar Giesen, Lagrangeville, NY (US); Egduard Ramon Jauregui, Aurora, CO (US); Patrick James McKeone, BEACON, NY (US); Zachary Thomas Dreiss, Wappingers Falls, NY (US)

(21) Appl. No.: 18/326,524

(22) Filed: May 31, 2023

(51) Int. Cl. H05K 3/02; H05K 3/38; H05K 3/46

(52) U.S. Cl. CPC H05K 3/022; H05K 3/384; H05K 3/4652

(57) ABSTRACT

A method of making a printed circuit board is disclosed. The method includes forming a plurality of layers. The method further includes forming a stack including the plurality of layers such that topmost and bottommost layers of the stack are copper layers and such that inner layers of the stack include resin layers and further copper layers. The method further includes thermocompressing the stack to form a panel such that the resin layers conform to the further copper layers and such that the copper layers bend around a perimeter of the inner layers. The method further includes separating a printed circuit board from the panel such that the printed circuit board's widest extent defines its final width.

### BACKGROUND

The present disclosure relates to the electrical and electronic device fields. In particular, the present disclosure relates to x-y shielding of signal paths within printed circuit boards (PCBs).

A printed circuit board (PCB) is a medium used in electrical and electronic engineering to connect electronic components to one another in a controlled manner. A basic PCB consists of a flat sheet of insulating material, also referred to as a substrate, and a layer of copper foil, laminated to the substrate. Chemical etching divides the copper into separate conducting lines, which may be referred to as “tracks” or “traces,” pads for connections, vias to interconnect different layers of copper, and other features such as solid conductive areas for electromagnetic shielding or other purposes. The traces function as wires fixed in place and are insulated from each other by air and the board substrate material. The surface of a PCB may have a coating that protects the copper from corrosion and reduces the chances of solder shorts between traces or undesired electrical contact with stray bare wires. For its function in helping to prevent solder shorts, the coating may be referred to as solder resist or solder mask.

The functional pattern to be etched into each copper layer of a PCB may be referred to as the “artwork.” The etching is typically performed using photoresist, which is coated onto the PCB and then exposed to light projected in the pattern of the artwork. The resist material protects the copper from dissolution into the etching solution. The etched board is then cleaned. A PCB design can be mass-reproduced in a way similar to the way photographs can be mass-duplicated from film negatives using a photographic printer.

A PCB can have multiple layers of copper, which are typically arranged in pairs. In such multi-layer boards, the layers of material are typically laminated together in an alternating sandwich: copper, substrate, copper, substrate, copper, etc. More specifically, two opposite sides of a substrate are typically covered with copper to form a laminated core, and then laminated cores are stacked together with a layer of uncured resin composite (or “pre-preg”) separating the copper of two adjacent laminated cores. Accordingly, such a sandwich includes, for example: copper, substrate, copper, pre-preg, copper, substrate, copper, etc.

Each of the conductive copper layers is patterned and etched in the manner described above, and any internal vias (that will not extend to both outer surfaces of the finished multilayer board) are plated through before the layers are laminated together. Only the external layers of copper need to be coated, because the inner copper layers are protected by the adjacent substrate layers. Multi-layer PCBs allow for much higher component density, because circuit traces on the inner layers would otherwise take up surface space between components. However, multilayer PCBs make repair, analysis, and field modification of circuits much more difficult and usually impractical.

The number of layers and the interconnections (e.g., vias) designed between them provide a general estimate of the board complexity. One of the simplest boards to produce is a two-layer board, in which a copper layer is arranged on both sides of a non-conductive substrate. In a two-layer board, the copper layers are referred to as external layers. Multi-layer boards sandwich additional internal layers of copper and insulation. A four-layer board adds significantly more routing options in the internal layers compared to the two-layer board. Additionally, some portion of the internal layers can be used as ground plane or power plane, to achieve better signal integrity, higher signaling frequencies, lower electromagnetic interference (EMI), and better power supply decoupling.

Using more layers allows for more routing options and better control of signal integrity but is also time consuming and costly to manufacture. Similarly, selection of the vias for the board also enables fine tuning of the board size, escaping of signals off complex integrated circuits (ICs), routing, and long-term reliability, but is tightly coupled with production complexity and cost.

For high-speed electronics the susceptibility of the signal paths to electromagnetic (EM) radiation requires measures be taken to maintain electromagnetic compatibility (EMC). EMC refers to the ability of electrical equipment and systems to function acceptably in their electromagnetic environments by limiting the unintentional generation, propagation, and reception of electromagnetic energy which may cause unwanted effects such as electromagnetic interference (EMI) or even physical damage in operational equipment. The goal of EMC is the correct operation of different equipment in a common electromagnetic environment.

When the signal paths in high-speed electronics are within a PCB, three common methods are employed to maintain EMC. The first method is to use parallel ground planes above and below the signal paths to provide shielding in the z direction and reference plane for the high-speed signal. The other two methods, edge plating and stitching vias, are commonly used to provide x-y direction shielding. Edge plating requires the ground planes within the PCB to be brought to the intended outside edge of the PCB pattern within a manufacturing panel. The edge is then routed out and additional expensive plating processes are used to coat the routed and exposed PCB edges in copper that is connected to ground. Accordingly, edge plating requires additional time and cost at the PCB manufacturing site and limits the ability to route on the surface layers to larger trace widths that are typically used in high-speed design. Stitching vias are vias that are patterned around the edge of a PCB at regular intervals. Forming the extra vias in this process requires extra time at the drilling machines and adds expense due to the high number of vias required. Accordingly, known methods for x-y shielding of signal paths are costly, time consuming, restrictive in terms of usable space and surface element characteristics, and require additional qualification to ensure quality control. These limitations drive a need for innovation to enable the next generation of high-speed electronics to function properly at an appropriate scale.

### SUMMARY

Embodiments of the present disclosure include a method of making a printed circuit board. The method includes forming a plurality of layers. The method further includes forming a stack including the plurality of layers such that topmost and bottommost layers of the stack are copper layers and such that inner layers of the stack include resin layers and further copper layers. The method further includes thermocompressing the stack to form a panel such that the resin layers conform to the further copper layers and such that the copper layers bend around a perimeter of the inner layers. The method further includes separating a printed circuit board from the panel such that the printed circuit board's widest extent defines its final width.

In such embodiments, because the panel is formed by thermocompressing the stack, the resin layers are forced to conform to the further copper layers, and the copper layers bend around the perimeter of the inner layers, thereby shielding the inner layers. Accordingly, the shielding of the inner layers of the panel is achieved efficiently, without requiring additional processing steps and without requiring additional surface area to be dedicated to plating the perimeter of the inner layers. As a result, the disclosed method of making a PCB enables efficient x-y shielding of signal paths within the PCB.

Embodiments of the present disclosure may include those in which forming the plurality of layers includes etching the further copper layers by removing copper from a substrate such that a leading edge of remaining copper extends 15 mils farther than half of the final width. Such embodiments facilitate the efficient x-y shielding of signal paths within the PCB, because the relative distance of the leading edge of remaining copper is completely covered by the conformed resin layers of the panel.

Embodiments of the present disclosure may include those in which forming the plurality of layers includes reducing a first width of first resin layers relative to the final width by a step back distance, and the first resin layers are adjacent to a center layer of the stack. Such embodiments facilitate the efficient x-y shielding of signal paths within the PCB, because the relative widths of the first resin layers and the center layer of the stack enable the stack to be formed into a panel and the perimeter of the panel to be covered with the copper layers during thermocompression of the stack.

Embodiments of the present disclosure may include those in which forming the plurality of layers includes reducing a second width of second resin layers relative to the first width by the step back distance, and the second resin layers are adjacent to the first resin layers and exclude the center layer. Such embodiments facilitate the efficient x-y shielding of signal paths within the PCB, because the relative widths of the second resin layers and the first resin layers enable the stack to be formed into a panel and the perimeter of the panel to be covered with the copper layers during thermocompression of the stack.

Embodiments of the present disclosure may include those in which thermocompressing the stack further includes curing the pre-preg layers such that the cured pre-preg layers are indistinguishable from the substrates. Such embodiments facilitate the efficient x-y shielding of signal paths within the PCB, because the pre-preg layers are cured in the same process during which the panel is formed and the perimeter is covered with the copper layers.

Additional embodiments of the present disclosure include a method of making a printed circuit board. The method includes arranging a plurality of layers to form a stack such that inner layers of the stack are arranged between outer copper layers and include copper coated substrates alternated with pre-preg layers. The method further includes thermocompressing the stack such that the pre-preg layers are forced into gaps in the copper coatings and such that the outer copper layers bend around a perimeter of the inner layers. The method further includes separating a printed circuit board from the thermocompressed stack.

In such embodiments, thermocompressing the stack forces the pre-preg layers into gaps in the copper coatings and bends the outer copper layers around a perimeter of the inner layers, thereby shielding the inner layers. Accordingly, the shielding of the inner layers of the panel is achieved efficiently, without requiring additional processing steps and without requiring additional surface area to be dedicated to plating the perimeter of the inner layers. As a result, the disclosed method of making a PCB enables efficient x-y shielding of signal paths within the PCB.

Embodiments of the present disclosure may include those in which the substrates and the pre-preg layers are resin layers comprising a polymeric matrix material and a fibrous material and arranging the plurality of layers includes arranging an equal number of layers above and below a center layer of the stack such that the center layer of the stack is a resin layer. Such embodiments facilitate the efficient x-y shielding of signal paths within the PCB, because the thermocompression of the stack causes the stack to narrow to the width of the center layer as it protrudes. Accordingly, because the protruding center layer is a resin layer, efficient separation of the PCB from the thermocompressed stack at the protrusion is facilitated without damaging any signal paths and such that the remaining resin layer can enable x-y shielding of signal paths within the PCB.

Additional embodiments of the present disclosure include a method of making a printed circuit board. The method includes forming a plurality of laminated cores including etching copper layers laminated on substrates. The method further includes forming a stack such that topmost and bottommost layers of the stack are further copper layers and such that inner layers of the stack include pre-preg layers alternated with the laminated cores. The method further includes thermocompressing the stack such that the pre-preg layers conform to the etched copper layers to form a panel and such that the further copper layers bend around a perimeter of the panel. The method further includes separating a printed circuit board from the panel such that the printed circuit board's widest extent defines its final width.

In such embodiments, thermocompressing the stack forces the pre-preg layers into gaps in the copper coatings and bends the outer copper layers around a perimeter of the inner layers, thereby shielding the inner layers. Accordingly, the shielding of the inner layers of the panel is achieved efficiently, without requiring additional processing steps and without requiring additional surface area to be dedicated to plating the perimeter of the inner layers. As a result, the disclosed method of making a PCB enables efficient x-y shielding of signal paths within the PCB.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

FIG. 1 illustrates a flowchart of an example method for forming a printed circuit board (PCB), in accordance with embodiments of the present disclosure.

FIG. 2 depicts a cross-sectional schematic view of an example of a structure for use in the performance of a portion of the example method of FIG. 1, in accordance with embodiments of the present disclosure.

FIG. 3 depicts a cross-sectional schematic view of an example of a structure following the performance of a portion of the example method of FIG. 1, in accordance with embodiments of the present disclosure.

FIG. 4 depicts a cross-sectional schematic view of an example of a structure following the performance of a portion of the example method of FIG. 1, in accordance with embodiments of the present disclosure.

FIG. 5 depicts a cross-sectional schematic view of an example of a structure following the performance of a portion of the example method of FIG. 1, in accordance with embodiments of the present disclosure.

FIG. 6 depicts a cross-sectional schematic view of an example of a structure following the performance of a portion of the example method of FIG. 1, in accordance with embodiments of the present disclosure.

### DETAILED DESCRIPTION

The present disclosure relates to the semiconductor device fields. In particular, the present disclosure relates to printed circuit boards (PCBs) and x-y shielding of signal paths within such PCBs. While the present disclosure is not necessarily limited to such applications, various aspects of the disclosure may be appreciated through a discussion of various examples using this context.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

Turning now to an overview of technologies that are more specifically relevant to aspects of the present disclosure, as mentioned above, edge plating is a known technique for x-y direction shielding of signal traces. Edge plating is clean and comprehensive. However, it is also expensive and creates a bottleneck in the manufacturing process. As described in further detail below, embodiments of the present disclosure provide structures and methods to enable x-y direction shielding of signal traces that do not suffer from the same limitations as edge plating. Moreover, embodiments of the present disclosure facilitate efficient x-y direction shielding of signal traces that can be accomplished without requiring additional procedures or equipment relative to what is already used for edge plating.

Embodiments of the present disclosure are particularly well suited to high-reliability products, such as, for example, servers. Compared to consumer products, such as, for example, laptops or cell phones, high-reliability products must have much higher reliability rates, or much lower failure rates. Accordingly, the processes used to form elements of high-reliability products must result in products that meet extremely high quality standards as well as extremely high yield standards.

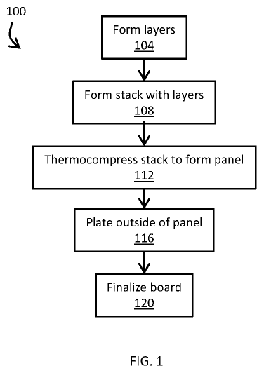

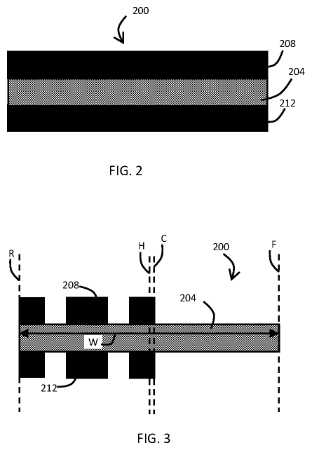

FIG. 1 depicts a flowchart of an example method 100 for forming a PCB, according to embodiments of the present disclosure. As discussed in further detail below (with reference to FIGS. 2-6), the method 100 includes stacking layers, including etched laminated cores, on top of one another with sheets of pre-preg between each core and on the outside layers. The stack further includes outermost copper layers. The method 100 further includes thermocompressing the stack such that the inner layers form a panel and the outermost copper layers cover the perimeter of the panel. The layers have specific dimensions relative to one another to enable x-y direction signal shielding without the drawbacks of current x-y signal shielding strategies.

FIG. 2 illustrates an example laminated core 200 to be used in the performance of the method 100. In particular, FIG. 2 illustrates a laminated core 200 prior to the performance of the method 100. The laminated core 200 includes a substrate 204 that is arranged between two copper layers 208, 212. The substrate 204 is made of a composite material, which includes fibrous material within a cured polymeric matrix or resin material. Such composite materials suitable for the substrate are known in the art and are not further described herein.

As shown in FIG. 2, a first copper layer 208 is arranged on a first side of the substrate 204 and a second copper layer 212 is arranged on a second side of the substrate 204. As shown, the second side of the substrate 204 is arranged opposite the first side of the substrate 204 such that the first and second copper layers 208, 212 are separated from one another by the substrate 204. As described in further detail below, in the performance of the method 100, the first and second copper layers 208, 212 and the substrate 204 of the laminated core 200 will form inner layers of the PCB.

As shown in FIG. 1, the method 100 begins with the performance of operation 104, wherein layers are formed. In accordance with at least one embodiment of the present disclosure, the performance of operation 104 includes the performance of a number of sub-operations. In accordance with at least one embodiment of the present disclosure, forming the layers in the performance of operation 104 includes chemically etching the copper layers of the laminated cores to form the desired signal traces. Accordingly, the portions of the copper layers that remain on each core following the performance of the etching process form the signal traces of the inner layers of the PCB.

Importantly, during the performance of this portion of operation 104, the etched patterns on the copper layers that will form the inner layers of the PCB are etched back from the intended edge of the PCB by a distance that is equivalent to half of the width of the final PCB plus 15 mils. In other words, the leading edge of each layer of patterned copper is 15 mils nearer than half the final width of the PCB to the intended edge of the PCB. For example, if the final width of the PCB is two inches, then the leading edge of the patterned copper is one inch and 15 mils measured from the same reference point as the width of the PCB.

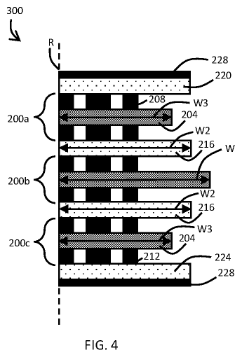

FIG. 3 illustrates the example laminated core 200 following the performance of this portion of operation 104 of the method 100. Accordingly, as shown, the substrate 204 of the laminated core 200 extends to a width W that is equivalent to the final width of the completed PCB, indicated by dashed line F, relative to a reference point, indicated by dashed line R. The final width F also represents the intended edge of the completed PCB. Half of the distance between the final width F and the reference point R is indicated by dashed line H. The leading edges of the patterned copper layers 208, 212 on the substrate 204 of the laminated core 200 are etched to a distance, indicated by dashed line C, which is 15 mils closer than the dashed line H to the final width F. As described in further detail below, the particular relative locations of the reference point R, leading edges of patterned copper C, and final width F enable the complete encapsulation of the patterned copper layers 208, 212 by the resin of the completed PCB, thereby improving the efficiency of x-y direction signal shielding processes.

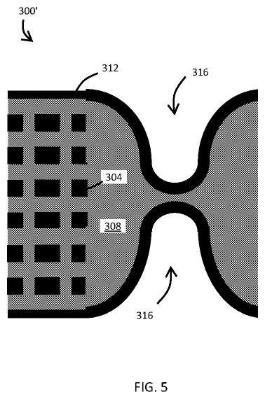

Returning to FIG. 1, in accordance with at least one embodiment of the present disclosure, the performance of operation 104 further includes reducing the widths of some of the substrates that will be stacked in the performance of operation 108. The reduction of the widths is described in further detail below and in the context of FIG. 4.

Following the performance of operation 104, the method 100 proceeds with the performance of operation 108, in which the layers of the PCB are stacked. In other words, the performance of operation 108 includes forming a stack with the layers of the PCB. In accordance with at least one embodiment of the present disclosure, the performance of operation 108 includes the performance of a number of sub-operations.

As described in further detail below, the performance of operation 104 further includes incrementally stepping back other substrate and pre-preg layers relative to the center layer as the layers will be stacked in the performance of operation 108. In other words, the widths of all other resin layers that will make up the inner layers of the PCB are reduced relative to the width of the center layer of the stack, which is also the width of the completed PCB. In accordance with at least one embodiment of the present disclosure, the widths of substrate layers can be reduced by routing, and the widths of pre-preg layers can be reduced by punching. In accordance with at least one embodiment of the present disclosure, the widths of the resin layers are reduced prior to forming the stack with the layers. In other words, the widths of the resin layers are reduced during the formation of the layers in the performance of operation 104 and the resulting stack formed with those layers in the performance of operation 108 is shown in FIG. 4.

As mentioned above, multilayer PCBs include more than one laminated core. In accordance with embodiments of the present disclosure that are directed toward multilayer PCBs, therefore, more than one laminated core will be used in the performance of the method 100. In accordance with an illustrative embodiment of the present disclosure described herein, the completed PCB includes three laminated cores, each of which will be separated from adjacent laminated cores by a layer of pre-preg, as described above. The use of three laminated cores is intended only as an illustrative example. In alternative embodiments of the present disclosure, the completed PCB can include more or fewer than three laminated cores. Regardless of the number of laminated cores, each laminated core is separated from adjacent laminated cores by a layer of pre-preg.

In accordance with embodiments of the present disclosure, the pre-preg layers are made of a composite material that includes fibrous material within an uncured or partially cured polymeric matrix or resin material. In accordance with at least one embodiment of the present disclosure, the fibrous material and the polymeric matrix or resin material can be the same as those of the composite material used for the substrates. In such embodiments, the pre-preg layers differ from the substrate layers only in that the polymeric matrix or resin material is uncured or partially cured in the pre-preg layers. Accordingly, the substrates and pre-preg layers may be collectively referred to herein as “resin layers.”

FIG. 4 illustrates an example PCB stack 300 following the performance of operation 108 of the method 100. As shown, the PCB stack 300 includes three laminated cores 200a, 200b, and 200c, each of which is separated from adjacent laminated cores by a pre-preg layer 216. The laminated cores 200a, 200b, and 200c and the pre-preg layers 216 will form the inner layers of the completed PCB.

For the completed PCB, one layer will be designated as the center layer of the PCB. As described in further detail below, the designation of the center layer is relevant for relative dimensioning of the layers of the PCB stack prior to the completion of the PCB. In some embodiments of the present disclosure, the center layer of the PCB will be a laminated core. In other embodiments of the present disclosure, the center layer of the PCB will be a pre-preg layer. Whether the center layer is a laminated core or a pre-preg layer, the center layer of the PCB is defined such that the PCB has an equal number of layers above and below the center layer. In other words, the center layer provides a line of symmetry for the PCB such that the PCB has the same number of layers on both sides of the center layer.

For embodiments in which the center layer of the PCB is a laminated core, when the laminated cores are arranged on top of one another to form the layers of the PCB, the center laminated core is that which is located in the center of the arrangement of laminated cores, such that an equal number of laminated cores is arranged above and below the center laminated core. Accordingly, when the PCB includes three laminated cores, as in the illustrative example described herein, the center layer is a laminated core, and one laminated core is arranged above the center laminated core and one laminated core is arranged below the center laminated core.

For such embodiments of the present disclosure, in which a laminated core is the center layer of the completed PCB, the width of the substrate of the center laminated core is also the width of the final PCB. Additionally, in accordance with at least one embodiment of the present disclosure, the width of the substrate of the center laminated core is also the distance from the reference point to the intended edge of the completed PCB. As described in further detail below, the widths of the substrates of the other laminated cores are defined relative to the width of the center laminated core such that the widths of the other laminated cores are less than the width of the center laminated core.

Returning to FIG. 4, the three laminated cores 200a, 200b, 200c are arranged such that the laminated core 200b is the center layer of the stack 300 that will form the completed PCB. As noted above, the width W of the center laminated core 200b is the width of the final PCB. Notably, to enable the performance of the method 100, the substrate or the pre-preg layer that is intended to be the center of the completed PCB must extend beyond alignment holes of the manufacturing panel (not shown). In the example embodiment shown in FIG. 4, the width W of the substrate 204 of the center laminated core 200b extends beyond such alignment holes.

In accordance with at least one embodiment of the present disclosure, the step distance by which each resin layer that will form an inner layer of the completed PCB is reduced relative to the next centermost resin layer is half the width of the completed PCB divided by three less than the number of resin layers. In other words, the step distance=(completed PCB width/2)/(number of resin layers−3). The numerator of the equation is the completed PCB width divided by 2, and the denominator of the equation is the number of resin layers of the completed PCB minus three. As an illustrative example, if the width of the completed PCB is 2.0 and the completed PCB includes 7 resin layers, the step distance is (2.0/2)/(7−3)=1/4=0.25.

Each resin layer is incrementally reduced by the step distance from the center layer. Accordingly, the widths of the first resin layers adjacent to the center layer are each reduced by the step distance relative to the width of the center layer. The widths of the next resin layers separated from the center layer by the first resin layers are then further reduced by a step distance relative to the widths of the first resin layers. This incremental reduction is repeated for each resin layer in the stack.

FIG. 4 illustrates the PCB stack 300 including the step backs formed during the performance of operation 104 of the method 100. As shown, each of the pre-preg layers 216 adjacent to the substrate 204 of the center laminated core 200b is reduced relative to the width W. In particular, the width W2 of each of the pre-preg layers 216 is equivalent to the width W of the completed PCB minus the step back distance. In accordance with at least one embodiment of the present disclosure, each of the pre-preg layers 216 is punched such that it extends the width W2 relative to the reference point R, and the width W2 is less than the width W by the step back distance.

The substrates 204 of the laminated cores 200a, 200c, which are separated from the center laminated core 200b by the pre-preg layers 216, are reduced relative to the width W2. In particular, the width W3 of each of the substrates 204 of the laminated cores 200a, 200c is equivalent to the width W2 of the pre-preg layers 216 minus the step back distance. In accordance with at least one embodiment of the present disclosure, the substrates 204 of the laminated cores 200a, 200c are routed such that they extend the width W3 relative to the reference point R, and the width W3 is less than the width W2 by the step back distance.

In accordance with at least one embodiment of the present disclosure, the performance of operation 108 further includes arranging outermost pre-preg layers and outermost copper layers on the top and bottom of the stack. As a result, the top layer of the stack formed in operation 108 is a copper layer laminated to a pre-preg layer which is arranged above the uppermost layer of the stack that will form an inner layer of the PCB. Similarly, the bottom layer of the stack formed in operation 108 is a copper layer laminated to a pre-preg layer which is arranged below the lowermost layer of the stack that will form an inner layer of the PCB.

As shown in FIG. 4, an outermost pre-preg layer 220 is arranged above the uppermost laminated core 200a. In particular, the pre-preg layer 220 is in direct contact with the copper layer 208 of the uppermost laminated core 200a. Additionally, an outermost pre-preg layer 224 is arranged below the lowermost laminated core 200c. The pre-preg layer 224 is in direct contact with the copper layer 212 of the lowermost laminated core 200c. Additionally, an outermost copper layer 228 is arranged above the outermost pre-preg layer 220 and an outermost copper layer 228 is arranged below the outermost pre-preg layer 224. In particular, the outermost copper layers 228 are laminated onto the surfaces of the outermost pre-preg layers 220, 224 that are opposite the rest of the layers of the stack 300.

Notably, unlike the pre-preg layers 216 and the substrates 204 of the uppermost and lowermost laminated cores 200a, 200c, the outermost pre-preg layers 220, 224 and the outermost copper layers 228 do not form the inner layers of the completed PCB. Accordingly, the outermost pre-preg layers 220, 224 and the outermost copper layers 228 are not stepped back relative to the width W of the center laminated core 200b in the same manner as the pre-preg layers 216 and the substrates 204. Instead, as described in further detail below, the outermost pre-preg layers 220, 224 and the outermost copper layers 228 have widths that enable those layers to encapsulate the inner layers of the completed PCB.

As shown in FIG. 4, following the performance of operation 108 of the method 100, the stack 300 that will be used for the completed PCB has been formed. Returning to FIG. 1, following the performance of operation 108, the method 100 proceeds with the performance of operation 112 in which the stack is thermocompressed to form a panel. In accordance with at least one embodiment of the present disclosure, the performance of operation 112 includes the performance of a number of sub-operations.

In accordance with at least one embodiment of the present disclosure, the performance of operation 112 includes thermocompressing the stack to form a panel. Thermocompressing the stack can be accomplished, for example, using a vacuum pressure hot press. The combination of increased temperature and pressure force the uncured or partially cured polymeric matrix or resin material of the pre-preg layers of the stack into the gaps between the patterned copper signal traces and also cure the polymeric matrix or resin material of the pre-preg layers in those gaps. Accordingly, following the performance of this portion of the method 100, the pre-preg layers may be materially integrated with the substrate layers of the laminated cores such that the pre-preg and substrate layers are subsequently indistinguishable from one another.

Thermocompressing the stack also bends the outermost copper layers such that valleys are formed around the intended edge of the PCB within the panel. Such bending may result in the incidental formation of cracks in the outermost copper layers. Such cracks are undesirable in the final PCB and are therefore addressed by further copper plating the outside layer of the PCB.

More specifically, in accordance with at least one embodiment of the present disclosure, following the performance of operation 112 of the method 100, the method proceeds with operation 116 wherein the outermost surface of the thermocompressed PCB panel is plated with copper. As described above, the outermost surface of the PCB stack is formed by the outermost copper layers. Accordingly, performing such copper plating applies an additional layer of copper to the outermost surface of the PCB stack, thereby repairing any of the incidental cracks in the outermost copper layers that formed during the bending of the outermost copper layers.

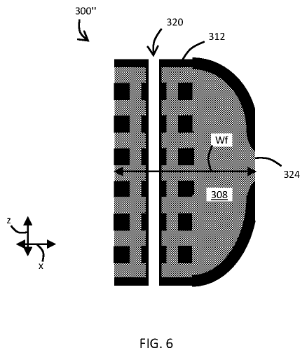

FIG. 5 illustrates the PCB panel 300′ formed during the performance of operations 112 and 116. As shown, the substrates of the laminated cores have become indistinguishable from the thermocompressed (and cured) pre-preg layers. Accordingly, the PCB panel 300′ includes signal traces 304, formed by the patterned copper layers 208, 212 (shown in FIG. 4), surrounded by insulative material 308, formed by the substrates 204 and the cured pre-preg layers 216 (shown in FIG. 4). The perimeter of the insulative material 308 is encapsulated by a copper coating 312, formed by the outermost copper layers 228 (shown in FIG. 4) and the additional layer of plated copper. The copper coating 312 provides x-y shielding for the signal traces 304. Notably, by forming the copper coating 312 in the above-described manner, x-y shielding of the signal traces 304 is accomplished without requiring the costly, time consuming, and physically restrictive processes required for edge plating.

As shown in FIG. 5, the PCB panel 300′ includes valleys 316 formed around the intended edge of the completed PCB by the bent copper coating 312. As described in further detail below, the valleys 316 provide a separation point for an individual PCB from the PCB panel 300′ to form a completed PCB.

Returning to FIG. 1, following the performance of operation 116, the method 100 proceeds with operation 120 in which the completed PCB is finalized. In accordance with at least one embodiment of the present disclosure, the performance of operation 120 includes the performance of a number of sub-operations.

In accordance with at least one embodiment of the present disclosure, the performance of operation 120 includes etching microstrip structures (not shown) on the PCB panel. In at least one such embodiment, the microstrip structures are chemically etched. Techniques for chemically etching such microstrip structures are known in the art and are not further described herein.

In accordance with at least one embodiment of the present disclosure, the performance of operation 120 further includes forming thru via holes through the PCB panel. In at least one such embodiment, the thru via holes are formed by drilling through the PCB panel. In at least one such embodiment, the performance of operation 120 further includes plating the thru via holes with a layer of copper. Techniques for forming and plating such thru via holes are known in the art and are not further described herein.

In accordance with at least one embodiment of the present disclosure, the performance of operation 120 further includes separating individual PCBs from the larger PCB panel. In at least one such embodiment, the individual PCBs can be separated by routing along the valleys formed in the performance of operations 112 and 116. Techniques for separating individual PCBs are known in the art and are not further described herein.

In accordance with at least one embodiment of the present disclosure, the performance of operation 120 includes connecting the copper coating to ground to form electromagnetic shielding in the x and y directions for the internal signal layers of the completed PCB.

FIG. 6 illustrates a plane of a cross-section of the completed PCB 300″ in which the z-direction and the x-direction of the three-dimensional object are visible. Accordingly, the y-direction is not visible as it is the direction going into and out of the page. Thus, with respect to the orientation of the PCB 300″ as shown in FIG. 6, the copper coating 312 shields the internal signal layers to facilitate electromagnetic compatibility in the horizontal direction and in the direction going into and out of the page.

FIG. 6 illustrates the completed PCB 300″ following the performance of operation 120 of the method 100. As shown, the completed PCB 300″ includes a copper plated thru via hole 320 and has been separated from the larger PCB panel 300′ at the valleys 316 (shown in FIG. 5). The completed PCB 300″ has a final width Wf that is equal to the width W of the center laminated core 200b (shown in FIG. 4).

By forming the PCB 300″ using the method 100, the set back boundary of the PCB is reduced relative to PCBs formed using edge plating or other existing methods. In particular, because the copper coating 312 is formed by bending the outermost copper layers with thermocompression and then plating the bent copper layer, the copper coating 312 is not required to wrap around the surface of the PCB panel, as in edge plating methods. The reduction in the set back boundary allows for more usable room on the surfaces of the PCB 300″ relative to other PCBs formed using existing methods, such as edge plating.

The completed PCB 300″ shown in FIG. 6 also includes an opening 324 formed in the copper coating 312 where the completed PCB 300″ was separated from the PCB panel 300′ at the valleys 316 (shown in FIG. 5). The opening 324 exposes a thickness of the insulative material 308. The exposure of non-metallic space provided by the opening 324 is used to ensure proper alignment of the layers of the PCB during manufacturing processes. Because the method 100 uses thermocompression to form the valleys 316, the thickness of the opening 324 can be as small as that of a single substrate of a laminated core. For example, the thickness of the opening 324 can be approximately 4 mils. Thus, by forming the opening 324 using thermocompression in the performance of the method 100, the opening 324 has a much smaller thickness than for PCBs formed using stitching vias to provide x-y direction shielding. Additionally, in accordance with at least one embodiment of the present disclosure, the PCB 300″ can be formed such that the layers closest to the opening 324 are ground or power layers, thereby ensuring no impact to the signal paths within the PCB 300″.

In addition to embodiments described above, other embodiments having fewer operational steps, more operational steps, or different operational steps are contemplated. Also, some embodiments may perform some or all of the above operational steps in a different order. Furthermore, multiple operations may occur at the same time or as an internal part of a larger process.

In the foregoing, reference is made to various embodiments. It should be understood, however, that this disclosure is not limited to the specifically described embodiments. Instead, any combination of the described features and elements, whether related to different embodiments or not, is contemplated to implement and practice this disclosure. Many modifications and variations may be apparent to those of ordinary skill in the art without departing from the scope and spirit of the described embodiments. Furthermore, although embodiments of this disclosure may achieve advantages over other possible solutions or over the prior art, whether or not a particular advantage is achieved by a given embodiment is not limiting of this disclosure. Thus, the described aspects, features, embodiments, and advantages are merely illustrative and are not considered elements or limitations of the appended claims except where explicitly recited in a claim(s).

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding of the various embodiments. However, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to one skilled in the art. Therefore, it is intended that the following claims be interpreted as covering all such alterations and modifications as fall within the true spirit and scope of the invention.

What is claimed is:

1. A method of making a printed circuit board, the method comprising:
forming a plurality of layers;
forming a stack including the plurality of layers such that topmost and bottommost layers of the stack are copper layers and such that inner layers of the stack include resin layers and further copper layers;
thermocompressing the stack to form a panel such that the resin layers conform to the further copper layers and such that the copper layers bend around a perimeter of the inner layers; and
separating a printed circuit board from the panel such that the printed circuit board's widest extent defines its final width.

2. The method of claim 1, further comprising:
plating the perimeter of the panel prior to separating the printed circuit board from the panel.

3. The method of claim 1, wherein forming the plurality of layers includes etching the further copper layers.

4. The method of claim 3, wherein etching the further copper layers includes removing copper from a substrate such that a leading edge of remaining copper extends 15 mils farther than half of the final width.

5. The method of claim 1, wherein forming the stack includes arranging an equal number of layers above and below a center layer of the stack such that the center layer of the stack is a resin layer.

6. The method of claim 5, wherein the center layer of the stack has a width that is equal to the final width.

7. The method of claim 5, wherein:
forming the plurality of layers includes reducing a first width of first resin layers relative to the final width by a step back distance, and
the first resin layers are adjacent to the center layer of the stack.

8. The method of claim 7, wherein:
forming the plurality of layers includes reducing a second width of second resin layers relative to the first width by the step back distance, and
the second resin layers are adjacent to the first resin layers and exclude the center layer.

9. The method of claim 8, wherein:
forming the plurality of layers includes calculating the step back distance by dividing a numerator by a denominator, and
the numerator is equal to half of the final width and the denominator is equal to three less than the number of resin layers in the stack.

10. The method of claim 1, wherein:
the resin layers include substrates and pre-preg layers, and
arranging the plurality of layers includes alternating the substrates and the pre-preg layers.

11. The method of claim 10, wherein:
the substrates are coated on opposite sides by the further copper layers such that alternating the substrates and the pre-preg layers includes arranging the pre-preg layers in direct contact with the further copper layers.

12. The method of claim 11, wherein thermocompressing the stack includes forcing the pre-preg layers to flow into gaps in the further copper layers.

13. The method of claim 12, wherein thermocompressing the stack further includes curing the pre-preg layers such that the cured pre-preg layers are indistinguishable from the substrates.

14. A method of making a printed circuit board, the method comprising:
arranging a plurality of layers to form a stack such that inner layers of the stack are arranged between outer copper layers and include copper coated substrates alternated with pre-preg layers;
thermocompressing the stack such that the pre-preg layers are forced into gaps in the copper coatings and such that the outer copper layers bend around a perimeter of the inner layers; and
separating a printed circuit board from the thermocompressed stack.

15. The method of claim 14, further comprising:
plating the bent outer copper layers prior to separating the printed circuit board from the thermocompressed stack.

16. The method of claim 15, wherein:
the substrates and the pre-preg layers are resin layers comprising a polymeric matrix material and a fibrous material, and
arranging the plurality of layers includes arranging an equal number of layers above and below a center layer of the stack such that the center layer of the stack is a resin layer.

17. The method of claim 16, wherein thermocompressing the stack cures the polymeric matrix material of the pre-preg layers.

18. A method of making a printed circuit board, the method comprising:
forming a plurality of laminated cores including etching copper layers laminated on substrates;
forming a stack such that topmost and bottommost layers of the stack are further copper layers and such that inner layers of the stack include pre-preg layers alternated with the laminated cores;
thermocompressing the stack such that the pre-preg layers conform to the etched copper layers to form a panel and such that the further copper layers bend around a perimeter of the panel; and
separating a printed circuit board from the panel such that the printed circuit board's widest extent defines its final width.

19. The method of claim 18, further comprising:
plating the perimeter of the panel prior to separating the printed circuit board from the panel.

20. The method of claim 18, wherein forming the plurality of laminated cores includes etching the copper layers such that a leading edge of remaining copper on the substrates extends 15 mils farther than half of the final width.
